(19) United States
(12) Patent Application Publication
(10) Pub. No.: US 2012/0021556 A1
(43) Pub. Date: Jan. 26, 2012

(54) DEPOSITION SYSTEM

(76) Inventors: Markus E. Beck, Scotts Valley, CA (US); Ashish Bodke, San Jose, CA (US); Ulrich Alexander Bonne, Sunnyvale, CA (US); Benyamin Buller, Perrysburg, OH (US); Raffi Garabedian, Los Altos, CA (US); Erel Milshtein, Cupertino, CA (US); Ming Lun Yu, Fremont, CA (US)

(21) Appl. No.: 13/189,251

(22) Filed: Jul. 22, 2011

Related U.S. Application Data
(60) Provisional application No. 61/366,782, filed on Jul. 22, 2010.

(51) Int. Cl. H01L 31/18; C23C 16/448; H01L 21/20

(52) U.S. Cl. 438/84; 438/478; 118/724; 257/E21.09; 257/E31.008

(57) ABSTRACT

A selenium deposition system can improve the selenium vapor distribution.

### CLAIM FOR PRIORITY

This application claims priority under 35 U.S.C. §119(e) to Provisional U.S. Patent Application Ser. No. 61/366,782, filed on Jul. 22, 2010, which is hereby incorporated by reference.

### TECHNICAL FIELD

This invention relates to a material deposition system.

### BACKGROUND

Thin-film deposition materials can be solid at room temperature. They can be used in production of photovoltaic modules by various deposition techniques. There are various challenges associated with thin-film material depositions, including achieving and maintaining uniform coating and good material utilization.

### DESCRIPTION OF DRAWINGS

FIG. 1 is a schematic of a selenium-deposition system.

FIG. 2 is a schematic of a selenium deposition system.

FIG. 3 is a schematic of a selenium deposition system.

### DETAILED DESCRIPTION

Photovoltaic devices can include multiple layers formed on a substrate (or superstrate). Copper indium gallium selenide (CIGS) based photovoltaic devices can be made from high temperature vacuum processes, such as co-evaporation, reaction of stacked elemental layers, or selenization of metal precursors. For example, a photovoltaic device can include a transparent conductive oxide (TCO) layer, a buffer layer, a semiconductor layer, and a conductive layer formed adjacent to a substrate. The semiconductor layer can include a semiconductor window layer and a semiconductor absorber layer, which can absorb photons. The semiconductor absorber layer can include CIGS. Each layer in a photovoltaic device can be created (e.g., formed or deposited) by any suitable process and can cover all or a portion of the device and/or all or a portion of the layer or substrate underlying the layer. For example, a “layer” can mean any amount of any material that contacts all or a portion of a surface.

Copper indium gallium (di)selenide (CIGS) is an I-III-VI₂ compound semiconductor material composed of copper, indium, gallium, and selenium. The material is a solid solution of copper indium selenide and copper gallium selenide. CIGS has rapidly gained popularity as absorber for photovoltaic applications. Highly efficiency CIGS photovoltaic films can be obtained by thermal co-evaporation of copper, indium and gallium in presence of selenium gas.

In CIGS photovoltaic module manufacturing, selenium gas is typically introduced into the deposition chamber by thermally heating a reservoir containing selenium pellets or powder. Because selenium is a solid at room temperature, selenium vapor can be introduced into the CIGS deposition chamber by thermally heating a reservoir containing selenium pellets or powder. The reservoir can be placed inside or outside of the deposition chamber. Since selenium evaporates in polymeric clusters containing several selenium atoms, selenium reactivity is low and significant amount of it is not deposited on the substrate. For example, selenium can condense on surfaces inside the deposition chamber besides the substrate. This can result in a poor utilization rate of selenium. In some embodiments, as little as 10-30% of selenium vapor is utilized in film growth. This same low utilization can occur in other material deposition processes.

A deposition system and related method are developed with improved utilization rate of deposition material by cracking the clusters in the vapor into smaller species. CIGS films can be deposited on a substrate, such as a glass substrate. The reaction of selenium with metals occurs on the surface of the glass substrate. By cracking the clusters into smaller species, such as Se₂ or selenium radicals, reactivity can be significantly increased, thus improving the utilization.

If the distance of selenium source to the substrate is large compared to the mean free path, the selenium radicals could potentially recombine in the gas phase, and the benefit of cracking would be lost. Therefore, it is important to introduce the cracked selenium species as close to the substrate as possible. Another benefit of reducing the distance between selenium source and substrate is that it would reduce the gas phase reaction between Cu and selenium resulting in formation of CuSeₓ particles. Regardless of whether selenium is cracked or not, it would still be beneficial to place the selenium source close to the substrate to improve utilization.

Uniformity of gas distribution is an issue for close source/substrate spacing, especially for large size substrates. Higher selenium concentration would be obtained at substrate location closer to the source than farther away from it.

The selenium deposition system and related method are developed to improve selenium gas distribution inside a reactive deposition chamber and to crack selenium clusters for improved reactivity and utilization.

In one aspect, a deposition system can include a deposition chamber including a substrate position at which a substrate can be positioned, a reservoir capable of containing a deposition material and being heated to vaporize the deposition material into a deposition vapor, and a cracker section connected to the reservoir, wherein the cracker is configured to crack the clusters in the deposition vapor while the deposition vapor flows toward the substrate position.

The cracker section can include a distribution manifold. The distribution manifold can be configured to direct the deposition vapor towards the substrate position. The distribution manifold can include a first chamber configured to receive the deposition vapor from the reservoir. The first chamber can include a tube. The first chamber can include at least one sidewall opening oriented in a first direction. The distribution manifold can include a second chamber connected to the first chamber. The second chamber can include a tube. The second chamber surrounds the first chamber. The second chamber can include at least one sidewall opening oriented in a different direction from the at least one sidewall opening in the first chamber such that deposition vapor flowing from the at least one sidewall opening of the first chamber into the second chamber flows around the first chamber before flowing through the at least one sidewall opening in the second chamber.

The cracker section can include a baffle section. The baffle section is configured to increase the number of collisions between the deposition vapor and the baffle section surface, compared to the number of collisions between a deposition vapor and an unbaffled component. The baffle section can be heated. The cracker section can include a baffle section connected to a distribution manifold. The baffle section can be between the reservoir and the distribution manifold. The deposition system can include a pipe connecting the baffle section and the distribution manifold.

The cracker section can be positioned in the deposition chamber. The cracker section can be positioned adjacent to the chamber. The cracker section can be heated to a temperature higher than that of the reservoir. At least a portion of the cracker section can include a material capable of obtaining desired deposition material composition and device efficiency. At least a portion of the cracker section can include a material including tantalum, stainless steel, or graphite. The cracker section can include a catalytic material to crack deposition material clusters. The cracker section can include a material including platinum, rhodium, rhenium, tantalum, molybdenum, tungsten, graphite, pyrolytic boron nitride, or combinations thereof.

At least a portion of the cracker section can be heated to a temperature between about 25 degrees C. and about 1200 degrees C. At least a portion of the cracker section can be heated to a temperature above about 100 degrees C. At least a portion of the cracker section can be heated to a temperature above about 200 degrees C. At least a portion of the cracker section can be heated to a temperature above about 400 degrees C. At least a portion of the cracker section can be heated to a temperature above about 600 degrees C.

The deposition system can include a valve between the reservoir and the cracker section to control the flux rate of the deposition vapor from the heated reservoir. The valve can be heated to a temperature higher than that of the reservoir. The valve can include a material including platinum, molybdenum, tantalum, chromium, niobium, stainless steel, or graphite, or combinations thereof. The flux rate of deposition vapor can be controlled by the temperature of the heated reservoir. The reservoir can be positioned adjacent to the chamber. The reservoir can be positioned in the chamber. The reservoir can include a material resistant to selenium corrosion including platinum, molybdenum, tantalum, chromium, niobium, stainless steel, or graphite, or combinations thereof.

The manifold can be positioned parallel to the width of a substrate at the substrate position. The at least one sidewall opening in the first chamber or second chamber can include a plurality of outlet holes for deposition vapor. The outlet holes can be designed for uniform distribution of deposition vapor flow along the manifold length. The sizes of the outlet holes can increase along the manifold length. The density of outlet holes can increase along the manifold length. The deposition system can include a conveyor capable of positioning a substrate at the substrate position.

In another aspect, a method of depositing a deposition material on a substrate by cracking clusters of deposition material in deposition vapor can include heating the deposition vapor to provide dissociation energy needed to break bonds in the deposition vapor to smaller species and flowing the deposition vapor through a cracker section comprising a catalytic material to crack deposition material clusters in the deposition vapor.

The deposition material can include a semiconductor material. The deposition material can include a Group V element. The deposition material can include a Group VI element. The deposition material can include selenium. The deposition material can include phosphorus. The deposition material can include arsenic. The deposition material can include sulfur. The deposition material can include tellurium. The deposition material can include antimony. At least a portion of the cracker section can be configured to increase the number of collisions between the deposition vapor and the cracker section.

In another aspect, a method of manufacturing a photovoltaic module can include evaporating selenium, heating the selenium vapor to provide dissociation energy needed to break Se—Se bonds in the selenium vapor to smaller species, flowing the selenium vapor through a cracker section comprising a catalytic material to crack selenium clusters, and depositing selenium on a substrate surface. The method can include transporting the substrate proximate to the selenium vapor.

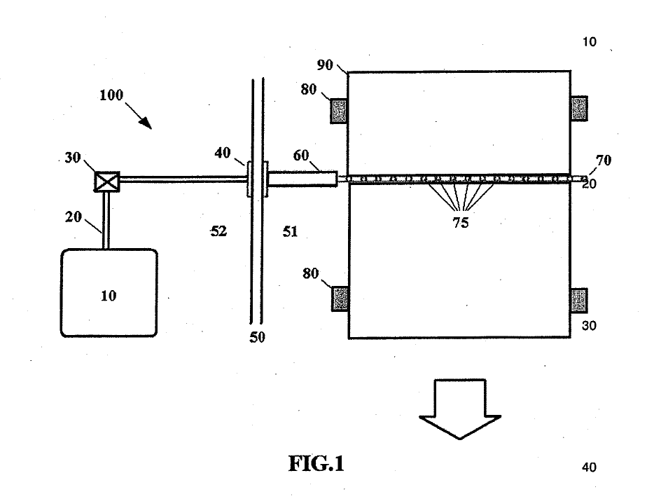

FIG. 1 depicts an embodiment of deposition system 100. Solid deposition material can be placed inside reservoir 10. The solid deposition material can be any material suitable for vaporizing and subsequently depositing on a substrate located at a substrate position in deposition chamber 50. Solid deposition material can be include a semiconductor material, such as a semiconductor absorber material. The solid deposition material can include a chalcogenide. The solid deposition material can include a Group V element. The solid deposition material can include a Group VI element. The solid deposition material can include selenium phosphorous, arsenic, sulfur, tellurium, or antimony, or any other suitable material. The solid deposition material can be in any suitable solid shape or form. For example, the solid deposition material can be in the form of pellets. The solid deposition material can be in powder form.

Reservoir 10 in which the solid deposition material is located can be heated. Reservoir 10 can be positioned inside 51 or outside 52 of deposition chamber 50. Reservoir 10 can be positioned adjacent to deposition chamber 50. The interior of deposition chamber 50 can be maintained at any suitable pressure, including reduced pressure. Deposition system 10 can include a pump to lower the interior pressure of deposition chamber 50. The interior of deposition chamber 50 can be maintained at any suitable pressure. The interior of deposition chamber 50 can be maintained in a vacuum state. In some embodiments, pressure inside deposition chamber 50 can be maintained in the range between 1E⁻⁶ to 1E-3 Torr. In some embodiments, reservoir temperature can determines deposition vapor flux rate. Deposition vapor flux rate can be exponentially dependent on the reservoir temperature. Reservoir temperature can be maintained in the range between about 275 degrees C. and about 500 degrees C. Temperature inside process chamber can be maintained in the range between about 25 degrees C. to about 1200 degree C., or between about 215 degrees C. and about 600 degrees C., or above about 100 degrees C., above about 200 degrees C., above about 400 degrees C., or above about 600 degrees C.

In some embodiments, reservoir 10 is placed outside the chamber due to space constraints and to avoid outgassing from external surface. Reservoir 10 can be configured to contain any suitable material. Reservoir 10 can be configured to contain the deposition material. Reservoir 10 can be configured to be heated to vaporize any suitable material, such as selenium.

Reservoir 10 can be connected to a cracker section. The cracker section can include any suitable components configured to crack, individually and/or cooperatively, material clusters in a deposition vapor formed by heating reservoir 10 to vaporize the solid material. The material clusters can include polymeric clusters of a solid material such as selenium deposition vapor. Cracking the material clusters forms smaller particles, such as molecular selenium and/or selenium radicals, which are more reactive than polymeric clusters and thus enable utilization of the solid deposition material at a higher rate. At a given temperature, the reactivity in the formation of compound thin films, such as gallium GaP and InSb, can be enhanced considerably by pre-dissociation to lower-meric species. Cracking clusters in the vapor can improve semiconductor film properties by reducing morphological defect density and improving photoluminescence efficiency.

The cracker section can include a distribution manifold 70 and/or a baffle section 60. Deposition vapor from reservoir 10 flows into the cracker section toward a substrate position where a substrate 90 can be positioned within deposition chamber 50. The substrate position can be adjacent to conveyor 80, which can position substrate 90 at the substrate position in deposition chamber 50.

The interactions between clusters (such as polymeric clusters) in the deposition vapor and the cracker section structure can crack the clusters. Cracker section 60 can be placed either inside 51 or outside 52 deposition chamber 50. In some embodiments, cracker section 60 can be placed inside deposition chamber 50 to minimize path of deposition material radicals after cracking. In some embodiments, the temperature of cracker section 60 can be greater than that of reservoir 10 and/or valve 30.

Distribution manifold 70 can have any suitable configuration for depositing the deposition vapor uniformly on substrate 90. For example, distribution manifold 70 can Manifold 70 can include a cylindrical tube with a plurality of sidewall openings such as outlet holes 75 for deposition vapor flow. Outlet holes 75 can be oriented so as to direct the deposition vapor towards substrate 90. Holes 75 can be designed for uniform distribution of deposition vapor flow along the manifold length. If the holes were to be constructed of identical size and spacing, the selenium pressure might drop across the manifold, causing selenium flow rate to decrease. Variance in selenium pressure can depend on the diameter of the chamber, the size of the holes, and/or the pressure of the selenium vapor.

In some embodiments, the hole size can be increased along the manifold length. The grading of hole sizes can be optimized using theoretical calculations and experimental results to achieve good uniformity. The number of holes 75 can be 10 or less for ease of production. In some embodiments, the number of holes can be significantly higher (>100) but will require more complicated manufacturing. In some embodiments, the hole size can be kept constant, but the density of holes can be increased along the manifold length. The hole spacing can be optimized using theoretical calculations and experimental results to achieve good uniformity.

In some embodiments, manifold 70 can include a first chamber including outlet holes 75 oriented in a first direction (e.g., away from the substrate position) and a second chamber connected to the first chamber include at least one sidewall opening oriented toward the substrate position. The first chamber can be positioned within the second chamber. Therefore, deposition vapor flows from the first chamber outlet holes 75 into the interior of the second chamber. The deposition vapor then can flow around the first chamber, increasing interaction with the chamber walls and cracking of clusters in the deposition vapor. Then, the deposition vapor can flow from the second chamber through the sidewall opening in the second chamber, toward the substrate position, to be deposited on substrate 90.

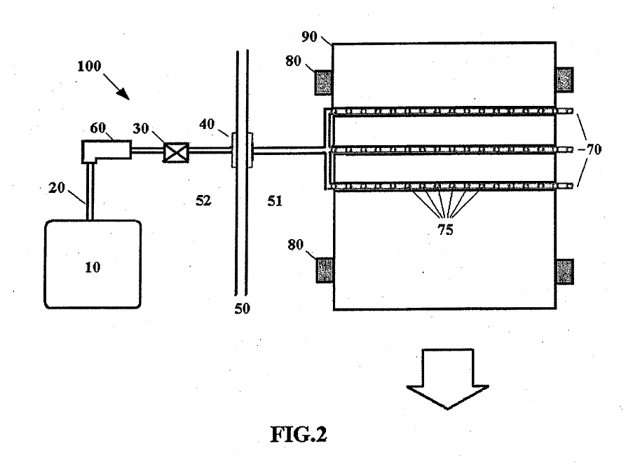

In some embodiments, manifold 70 can be positioned parallel to the width of substrate 70 or any suitable orientation. Manifold 70 can be heated to prevent surface condensation. The manifold temperature can be selected to minimize recombination of cracked deposition material species. In some embodiments, selenium channel can be divided into two sections with identical cross section area. The flow will evenly distribute in the two sections, each section bearing half of the total flow rate. In some embodiments, each of the two sections can be divided into two additional sections, which can further be divided into two additional sections. In this way the resistance encountered by se gas will be identical along the eight sections. This will ensure uniform flow across the substrate width. FIG. 2 depicts an embodiment of deposition system 100 can include multi-tube manifold 70. Deposition system 100 can also include a “binary manifold” configuration used to create a distribution tube with 8, 16, 32 . . . outlet holes with uniform flow rate from each hole.

In CIGS manufacture, cracking can be achieved either by using high temperatures or by using RF plasma. In this present invention, selenium is primarily cracked using thermal means. High temperature can provide the dissociation energy needed to break the Se—Se bonds to smaller species. In some embodiments, temperature in cracker section 60 can be higher than that in reservoir 10. The cracker temperature can be optimized to obtain desired selenium composition and device efficiency.

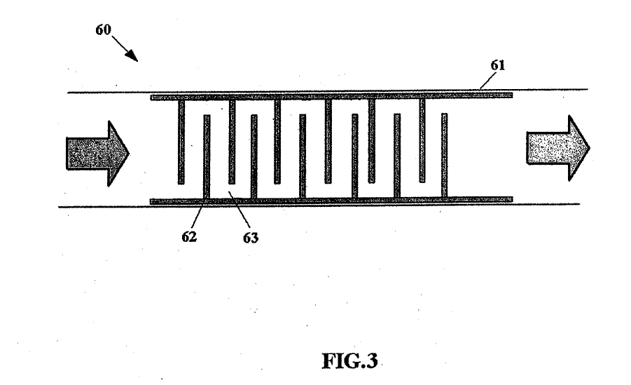

Referring to FIG. 3, baffle section 60 can include enclosure 61, baffle structure 62, and vapor channel 63. Baffle section 60 can include baffle structure 62 maintained at high temperature. Baffle structure 62 and vapor channel 63 can be designed so as to allow large number of collisions between the clusters in the deposition vapor (such as selenium vapor) and the high temperature baffle surface.

It is known that not only the temperature but also electronic properties of the cracking surface determine cracking efficiency. In some embodiments, the cracking section can include a material plated or otherwise incorporated into the interior surface structure of a portion of the cracker section surface is catalytic in nature. In some embodiments, a portion of the cracker section, such as baffle structure 62, or an interior surface of distributor manifold 70, can be made of material optimized for highest cracking efficiency for a given deposition vapor. For example, the catalytic material used, for example, in the case of a selenium deposition material, can include one or more of platinum, rhodium, rhenium, tantalum, molybdenum, tungsten, graphite, pyrolytic boron nitride, or combinations thereof (such as platinum and rhodium, e.g., Pt—Rh, or combinations of tungsten and rhenium, e.g., W—Re), or any other suitable material. Additionally, the same or other portions of the cracker section can include a material or combination of materials, including catalytic materials, capable of obtaining desired deposition material composition and device efficiency, for example, by suitable cracking the deposition vapor. Examples of such materials include, but are not limited to, tantalum, stainless steel, and graphite.

In some embodiments, the temperature of baffle structure 62 can be optimized depending on flux rate, proximity to substrate and the temperature of hot box. In some embodiments, Se cracking efficiency can be determined by baffle temperature and manifold temperature. In some embodiments, both baffle and manifold temperatures can be maintained in the range above 600 degrees C. In some embodiments, the deposition system can be used in any other suitable material deposition for higher efficiency, such as sulfur, hydrogen sulfide, or hydrogen selenide.

Deposition system 100 can include valve 30 located downstream of reservoir 10 to control the deposition vapor flux rate. Flux rate can alternatively be controlled by reservoir temperature, but the later might have much slower response time. Valve 30 can be heated to prevent condensation or clogging issues. In some embodiments, the temperature of valve 30 can be greater than that of reservoir 10. Downstream of valve 30 is the cracker section used to crack deposition material clusters in selenium vapor. Valve 30 and reservoir 10 can be formed from any suitable material with any suitable property, such as resistance to corrosion by the deposition material. Examples of such materials include, but are not limited to, platinum, molybdenum, tantalum, chromium, niobium, stainless steel, and graphite, and combinations thereof. Value 30 and/or reservoir 10 can be plated, for example, with chromium or tantalum. Pipe 20 can be connected to reservoir 10 to outletting deposition vapor.

A number of embodiments of the invention have been described. Nevertheless, it will be understood that various modifications may be made without departing from the spirit and scope of the invention. It should also be understood that the appended drawings are not necessarily to scale, presenting a somewhat simplified representation of various preferred features illustrative of the basic principles of the invention.

What is claimed is:

1. A deposition system comprising:
a deposition chamber comprising a substrate position at which a substrate can be positioned;
a reservoir capable of containing a deposition material and being heated to vaporize the deposition material into a deposition vapor; and
a cracker section connected to the reservoir, wherein the cracker section is configured to crack clusters in the deposition vapor while the deposition vapor flows toward the substrate position.

2. The deposition system of claim 1, wherein the cracker section comprises a distribution manifold.

3. The deposition system of claim 2, wherein the distribution manifold is configured to direct the deposition vapor towards the substrate position.

4. The deposition system of any one of claims 2-3, wherein the distribution manifold comprises a first chamber configured to receive the deposition vapor from the reservoir.

5. The deposition system of claim 4, wherein the first chamber comprises a tube.

6. The deposition system of any one of claims 4-5, wherein the first chamber comprises at least one sidewall opening oriented in a first direction.

7. The deposition system of any one of claims 4-6, wherein the distribution manifold comprises a second chamber connected to the first chamber.

8. The deposition system of claim 7, wherein the second chamber comprises a tube.

9. The deposition system of any one of claims 7-8, wherein the second chamber surrounds the first chamber.

10. The deposition system of claim 9, wherein the second chamber comprises at least one sidewall opening oriented in a different direction from the at least one sidewall opening in the first chamber such that deposition vapor flowing from the at least one sidewall opening of the first chamber into the second chamber flows around the first chamber before flowing through the at least one sidewall opening in the second chamber.

11. The deposition system of any one of the preceding claims, wherein the cracker section comprises a baffle section.

12. The deposition system of claim 11, wherein the baffle section is configured to increase the number of collisions between the deposition vapor and the baffle section surface, compared to the number of collisions between a deposition vapor and an unbaffled component.

13. The deposition system of claim 11, wherein the baffle section is heated.

14. The deposition system of claim 1, wherein the cracker section comprises a baffle section connected to a distribution manifold.

15. The deposition system of claim 14, wherein the baffle section is between the reservoir and the distribution manifold.

16. The deposition system of claim 14, further comprising a pipe connecting the baffle section and the distribution manifold.

17. The deposition system of any one of the preceding claims, wherein the cracker section is positioned in the deposition chamber.

18. The deposition system of any one of claims 1-17, wherein the cracker section is positioned adjacent to the chamber.

19. The deposition system of any of the preceding claims, wherein the cracker section is heated to a temperature higher than that of the reservoir.

20. The deposition system of any of the preceding claims, wherein at least a portion of the cracker section comprises a material capable of obtaining desired deposition material composition and device efficiency.

21. The deposition system of claim 20, wherein at least a portion of the cracker section comprises a material selected from the group consisting of tantalum, stainless steel, and graphite.

22. The deposition system of any one of the preceding claims, wherein the cracker section comprises a catalytic material to crack deposition material clusters.

23. The deposition system of claim 22, wherein the cracker section comprises a material selected from the group consisting of platinum, rhodium, rhenium, tantalum, molybdenum, tungsten, graphite, pyrolytic boron nitride, and combinations thereof.

24. The deposition system of any one of the preceding claims, wherein at least a portion of the cracker section is heated to a temperature between about 25 degrees C. and about 1200 degrees C.

25. The deposition system of claim 1, wherein at least a portion of the cracker section is heated to a temperature above about 100 degrees C.

26. The deposition system of claim 25, wherein at least a portion of the cracker section is heated to a temperature above about 200 degrees C.

27. The deposition system of claim 26, wherein at least a portion of the cracker section is heated to a temperature above about 400 degrees C.

28. The deposition system of claim 27, wherein at least a portion of the cracker section is heated to a temperature above about 600 degrees C.

29. The deposition system of any one of the preceding claims, further comprising a valve between the reservoir and the cracker section to control the flux rate of the deposition vapor from the heated reservoir.

30. The deposition system of claim 29, wherein the valve is heated to a temperature higher than that of the reservoir.

31. The deposition system of any one of claims 29-30, wherein the valve comprises a material resistant to corrosion selected from the group consisting of platinum, molybdenum, tantalum, chromium, niobium, stainless steel, and graphite, and combinations thereof.

32. The deposition system of any one of the preceding claims, wherein the flux rate of deposition vapor is controlled by the temperature of the heated reservoir.

33. The system of any one of the preceding claims, wherein the reservoir is positioned adjacent to the chamber.

34. The deposition system of any one of the preceding claims, wherein the reservoir is positioned in the chamber.

35. The deposition system of any one of the preceding claims, wherein the reservoir comprises a material resistant to selenium corrosion selected from the group consisting of platinum, molybdenum, tantalum, chromium, niobium, stainless steel, and graphite, and combinations thereof.

36. The deposition system of any one of claims 2-27, wherein the manifold is positioned parallel to the width of a substrate at the substrate position.

37. The deposition system of any one of claims 6-10, wherein the at least one sidewall opening in the first chamber or second chamber comprises a plurality of outlet holes for deposition vapor.

38. The deposition system of claim 37, wherein the outlet holes are designed for uniform distribution of deposition vapor flow along the manifold length.

39. The deposition system of any one of claims 37-38, wherein the sizes of the outlet holes increase along the manifold length.

40. The deposition system of any one of claims 37-39, wherein the density of outlet holes increases along the manifold length.

41. The deposition system of any one of the preceding claims, further comprising a conveyor capable of positioning a substrate at the substrate position.

42. A method of depositing a deposition material on a substrate by cracking clusters of deposition material in deposition vapor comprising:
heating the deposition vapor to provide dissociation energy needed to break bonds in the deposition vapor to smaller species; and
flowing the deposition vapor through a cracker section comprising a catalytic material to crack deposition material clusters in the deposition vapor.

43. The method of claim 26, wherein the deposition material comprises a semiconductor material.

44. The method of claim 26, wherein the deposition material comprises a Group V element.

45. The method of claim 26, wherein the deposition material comprises a Group VI element.

46. The method of claim 26, wherein the deposition material comprises selenium.

47. The method of claim 26, wherein the deposition material comprises phosphorus.

48. The method of claim 26, wherein the deposition material comprises arsenic.

49. The method of claim 26, wherein the deposition material comprises sulfur.

50. The method of claim 26, wherein the deposition material comprises tellurium.

51. The method of claim 26, wherein the deposition material comprises antimony.

52. The method of any of the preceding claims, wherein at least a portion of the cracker section is configured to increase the number of collisions between the deposition vapor and the cracker section.

53. A method of manufacturing a photovoltaic module comprising:
evaporating selenium;
heating the selenium vapor to provide dissociation energy needed to break Se—Se bonds in the selenium vapor to smaller species;
flowing the selenium vapor through a cracker section comprising a catalytic material to crack selenium clusters; and
depositing selenium on a substrate surface.

54. The method of claim 53, further comprising transporting the substrate proximate to the selenium vapor.
